(19) United States
(12) Patent Application Publication
(10) Pub. No.: US 2004/0239309 A1
(43) Pub. Date: Dec. 2, 2004

(54) Remotely controllable oscilloscope

(76) Inventors: Andrew Harvey Barr, Roseville, CA (US); Robert William Dobbs, Granite Bay, CA (US)

Correspondence Address: HEWLETT-PACKARD COMPANY, Intellectual Property Administration, P.O. Box 272400, Fort Collins, CO, 80527-2400, US

(21) Appl. No.: 10/446,408

(22) Filed: May 27, 2003

(51) Int. Cl. G01R 13/20

(52) U.S. Cl. 324/121 R

(57) ABSTRACT

A probe contains integrated oscilloscope controls. This allows the technician to operate the controls while holding the probe. Consequently, changes can be made at the probe without the technician needing to go to the oscilloscope to change controls. The programmable oscilloscope embodiment is for broad use with any oscilloscope where controls can be put on the probe body.

### BACKGROUND

Many electronic devices, such as computers, include circuit boards, on which are mounted electronic components such as a processor or memory. When these components malfunction or when the devices are beta tested, a technician typically probes the components with a probe coupled to an oscilloscope to determine the cause of the malfunction or to confirm the device operates as intended.

There are different types of probes for different uses. Passive probes are used to measure typical signal and voltage levels. To measure signals with fast rise times, high-speed active or differential probes are used for more accurate results.

For example, referring to FIG. 1, a technician (not shown) connects a high-frequency probe 10 to an oscilloscope 11 with a probe cable 13 and then probes 10 a node 17 on a circuit board 16. Often, however, when the technician probes the node 17, he needs to hold the probe 10 in position with one of his hands. This may make it difficult for the same technician to maneuver the controls 14 on the oscilloscope 11 or to look at and evaluate the display on the oscilloscope screen 12, particularly if the technician has to take his eyes off of the probe 10 or if the oscilloscope 11 is out of the technician's reach. In such a situation, the probe 10 may slip and at best lose the signal to be measured and at worst may damage the circuit board 16. Furthermore, if the measurement requires two probes, a lone technician cannot hold both probes and simultaneously maneuver the oscilloscope controls 14.

There are a number of solutions to this problem. The technician could mount the probe in a fixed position and secure it permanently or semi-permanently to the device under test to free up his hands to control the scope and free up his eyes to look at the screen. This solution allows a single technician to both make measurements with one or multiple probes and also to control the oscilloscope, but requires a means to attach the probes to the device. Although such attachment is possible and is used in situations where repeated measurements need to be taken over time, it is often too time consuming to merely make a quick measurement and potentially causes damage to the system under test.

Still referring to FIG. 1, another solution is to use a voice-controlled oscilloscope 11. This allows the technician to hold the scope probe(s) 10 to measure a signal or the node 17 while controlling the scope 11 via a microphone 15. A problem with this solution is that oscilloscope measurements are often made in a noisy environment such as a lab where voice control does not work well or at all. Typically, only about one in ten voice commands actually provide the desired response, such that the technician must continually repeat a voice command until the oscilloscope 11 properly implements the command.

Yet another solution is having a second technician control the oscilloscope 11 while a first technician holds the probe(s), but using two technicians to make a measurement is often an inefficient use of resources.

### SUMMARY

In one aspect of the invention, a probe includes oscilloscope controls so that a technician can control the oscilloscope while probing a circuit node. The controls may be positioned on the probe such that the technician can use his probe-holding hand, his other hand, or both to control the oscilloscope.

### BRIEF DESCRIPTION OF THE DRAWINGS

FIG. 1 is a block diagram of a conventional oscilloscope and signal probe.

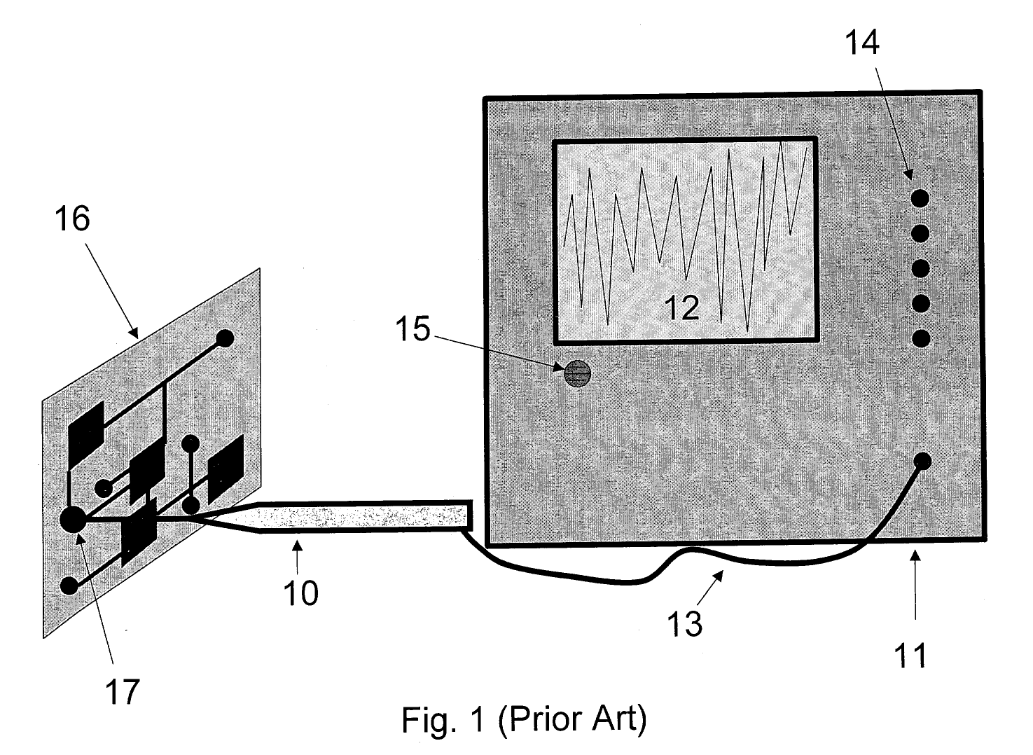

FIG. 2 is a block diagram of a probe incorporating oscilloscope controls and an oscilloscope according to an embodiment of the invention.

FIG. 3 is a block diagram of a probe incorporating programmable oscilloscope controls and an oscilloscope according to an embodiment of the invention.

FIG. 4 is a block diagram of the probe of FIG. 3, and a personal-computer-based oscilloscope according to an embodiment of the invention.

### DESCRIPTION OF THE INVENTION

The following discussion is presented to enable a person skilled in the art to make and use the invention. Various modifications to the disclosed embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

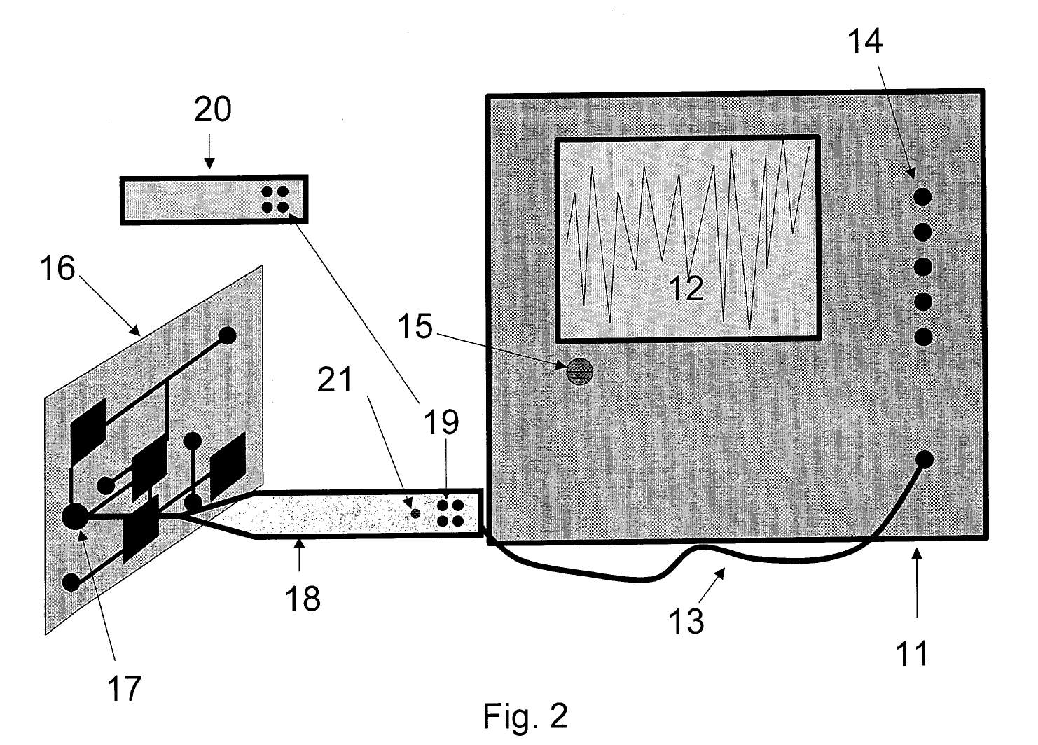

Referring to FIG. 2, in one embodiment of the invention, a probe 18 for probing a node 17 includes one or more oscilloscope controls 19. The embedded controls 19 may be hard-wired to provide a predetermined set of commands to the oscilloscope 11, or may be programmable.

Still referring to FIG. 2, the embedded controls 19 may take many forms. For example, they may be buttons located on the body of the probe 18 that the technician can push in certain sequences while he is holding the probe to give the desired function to the scope 11, they may be hard-wired one-function buttons, or they may be completely programmable such that pressing a single button or pressing a sequence of buttons can implement respective selected functions. Placement of the buttons 19 on the probe body is designed to allow for easy pressing of the buttons with the same hand used to hold the probe. In one embodiment, the functionality of the embedded button controls 19 can be programmed from the front-panel controls 14 of the oscilloscope 11, or one or more of the buttons 19 can be enabled or disabled via the controls 14. Examples of oscilloscope functions that can be controlled via hard-wired buttons 19 are: start, stop, store waveform and auto scale. Examples of oscilloscope functions that can be controlled via programmable buttons 19 are: changing the trigger input, changing the time scale, and changing the voltage scale. Thus, the controls 19 allow a single technician to control the functionality of the oscilloscope 11 and at the same time make a measurement without needing help from a second technician, or needing to maneuver the front-panel controls 14 with his free hand. In one embodiment, the embedded controls 19 include an analog dial capability and in another embodiment, an up/down step function capability.

Still referring to FIG. 2, the controls 19 are connected to the scope 11 via the cable 13 that connects the probe 18 to the scope 11 by including control wires (not shown) within the cable 13. These wires are routed within the cable 13 without any interference or negative impact to the measurement accuracy. Alternatively, the controls 19 may be coupled to the scope 11 via a wireless link. Furthermore, the scope 11 may be operable with multiple probes 18 each having controls 19. In such an embodiment, the controls 19 on either probe 18 may be used to control the oscilloscope 11, or the technician may disable one set of controls 19. In one embodiment, a probe 18 with controls 19 may also include an embedded speaker 21 providing audible feedback to the technician when a control 19 has been used.

Still referring to FIG. 2, in one embodiment, the controls 19 are separate from the body of the probe 18 and disposed in a remote unit 20 similar to a TV remote control, which is used to control the oscilloscope 11.

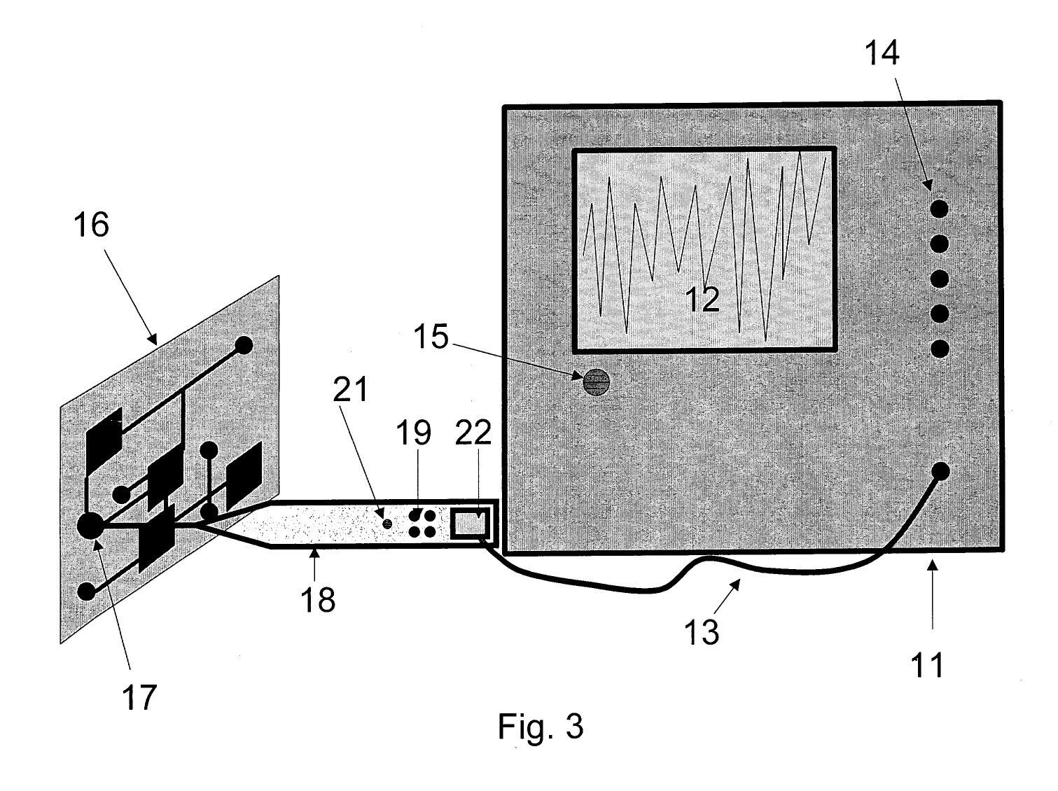

Referring to FIG. 3, in one embodiment, an embedded display 22 allows for remote control of the oscilloscope 11 with an interface similar to that of a cell phone. This allows for the ability to see a small copy of the oscilloscope screen output 12 on the embedded display screen 22. This brings the technician, the controls 19, the speaker 21, and the display (on the screen 22) all into close proximity and thus allows the technician to focus on probing the node 17 without having to look away from the general area of the node 17. In one embodiment, the quality of the embedded display screen 22 is low and is sufficient only to show the existence of a signal. In another embodiment, the quality is higher requiring more computational power to show more detail.

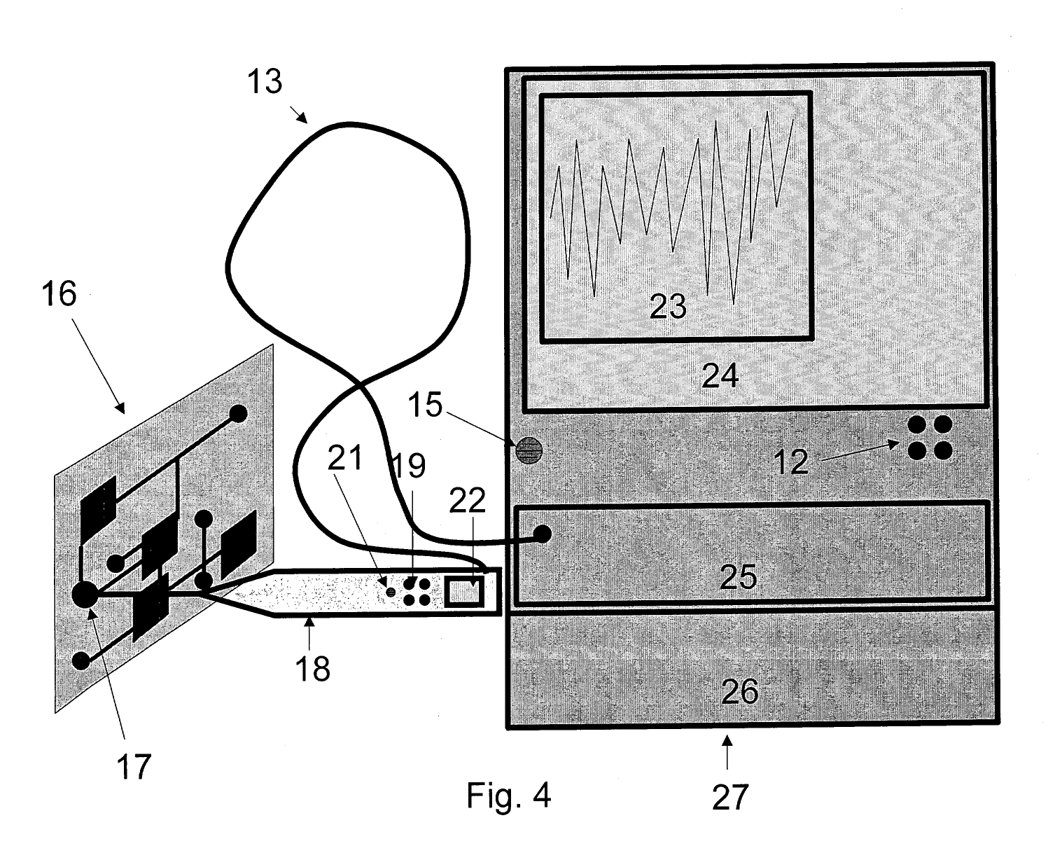

Referring to FIG. 4, the probe 18 of FIG. 3 can be used in conjunction with an oscilloscope that is implemented into a computer 27 such as a personal computer according to an embodiment of the invention. This integration may allow for easier programming of the probe 18 and allows for integration of the scope display 23 into the computer display console 24. The functionality of a computer 27 may allow for easier programming of the oscilloscope 25 using the keyboard 26 and display console 24 if available. It also may allow for multiple display windows for multiple scope displays 23 on the computer's console 24. In one embodiment of the invention, the probe display 22 can be remotely controlled via the controls 19 to display any of the scope display windows 23 that the technician needs view.

Other embodiments of the programmable probe are contemplated. For example, the probe 18 of FIG. 2 may also be used with the scope implemented on the computer 27 of FIG. 4. Also, it is possible to take advantage of computer networking and have a programmable probe be part of one computer system networked to a distant remote and separate computer system with the oscilloscope embedded. This allows for remote diagnostics and repair. For example, just as remote medical diagnostics are made today via the internet to remote and isolated individuals and locations, remote electrical diagnostics and repairs can be made with the expert technician not physically present at the remote site where there is only a programmable probe connected to a local computer operated by a physically remote technician's aide.

What is claimed is:

1. A signal probe, the probe comprising:
a body; and
a control disposed in the body and operable to remotely control an oscilloscope.

2. The signal probe of claim 1 wherein the control comprises a push button.

3. The signal probe of claim 1, further comprising a cable operable to transmit a signal from the control to the oscilloscope.

4. The signal probe of claim 1, further comprising a speaker disposed in the body and operable to provide audible control feedback.

5. The signal probe of claim 1, further comprising a wireless transmitter operable to transmit a signal from the control to the oscilloscope.

6. The signal probe of claim 1 wherein the control is programmable.

7. The signal probe of claim 1 wherein the control is programmable via the oscilloscope.

8. A system, comprising:
an oscilloscope; and
a signal probe operable to be coupled to and to control a function of the oscilloscope.

9. The system of claim 8 wherein the oscilloscope includes a front-panel control operable to control the function of the oscilloscope; and
the probe includes oscilloscope control operable to be programmed from the oscilloscope to control the function.

10. The signal probe of claim 8, further comprising a cable operable to transmit a signal to control the function of the oscilloscope.

11. The signal probe of claim 8, further comprising a wireless transmitter operable to transmit a signal to control the function of the oscilloscope.

12. The system of claim 8 wherein the oscilloscope includes a scope
display operable to view the output of the oscilloscope; and
the probe includes a probe display operable to view the output of the oscilloscope.

13. A system, comprising:
an oscilloscope; and
a signal probe operable to be coupled to the oscilloscope; and
a remote unit operable to be coupled to the oscilloscope and control a function of the oscilloscope.

14. The remote unit of claim 13 wherein the control comprises a push button.

15. The remote unit of claim 13, further comprising a wireless transmitter operable to transmit a signal from the control to the oscilloscope.

16. The remote unit of claim 13 wherein the control is programmable.

17. The remote unit of claim 13 wherein the control is programmable via the oscilloscope.

18. A method, comprising:
probing a signal with a probe; and
remotely controlling an oscilloscope that receives the probed signal.

19. The method of claim 18 wherein remotely controlling the oscilloscope includes pushing a button disposed on the probe.

20. The method of claim 18 wherein remotely controlling the oscilloscope includes pushing a button disposed on a remote unit.

21. The method of claim 18 wherein remotely controlling the oscilloscope includes hearing feedback from a speaker disposed on the probe.

22. The method of claim 18, further comprising:
displaying information to the on a screen disposed in the probe.

23. The method of claim 18 further comprising:
allowing the probed signal to propagate through a cable from the probe to the oscilloscope; and
transmitting a control signal for controlling the oscilloscope from the probe to the oscilloscope via the cable.

24. The method of claim 18 wherein remotely controlling the oscilloscope includes programming a button disposed on the probe.

25. The method of claim 18 wherein remotely controlling the oscilloscope includes programming via the oscilloscope.
